(19) United States
(12) Patent Application Publication
(10) Pub. No.: US 2026/0164810 A1
(43) Pub. Date: Jun. 11, 2026

(54) NOVEL METHOD TO IMPROVE ELECTROSTATIC DISCHARGE (ESD) ROBUSTNESS

(71) Applicant: QUALCOMM Incorporated, San Diego, CA (US)

(72) Inventors: Jaseem AHAMMED, San Marcos, CA (US); Patrick ISAKANIAN, El Dorado Hills, CA (US); Ashwin SETHURAM, San Clemente, CA (US)

(21) Appl. No.: 18/977,621

(22) Filed: Dec. 11, 2024

(51) Int. Cl. H10D 89/60; H03K 19/003

(52) U.S. Cl. CPC H10D 89/819; H03K 19/00315; H10D 89/921

(57) ABSTRACT

A method for electrostatic discharge (ESD) protection of a chip is disclosed. The chip includes a driver, a first tri-state buffer, and a second tri-state buffer, wherein an output of the driver is coupled to a pad, an output of the first tri-state buffer is coupled to a first input of the driver, and an output of the second tri-state buffer is coupled to a second input of the driver. The method includes, during a normal mode, driving the first input of the driver with a first data signal using the first tri-state buffer and driving the second input of the driver with a second data signal using the second tri-state buffer. The method also includes detecting an ESD event on the pad, and, in response to detecting the ESD event, putting each of the first tri-state buffer and the second tri-state buffer in a high impedance output state.

### BACKGROUND

### Field

Aspects of the present disclosure relate generally to electrostatic discharge (ESD) protection, and more particularly, to on-chip ESD protection.

### BACKGROUND

Electronic components on a chip are susceptible to damage from an electrostatic discharge (ESD) event. For example, an ESD event may destroy the gate oxide of an active device (e.g., transistor) on the chip. Damage caused by ESD events may reduce manufacturing yields and/or lead to operational failures of electronic components. To protect against an ESD event, the chip includes one or more ESD protection circuits.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a pad, and a driver having a first input, a second input, and an output, wherein the output of the driver is coupled to the pad. The chip also includes a pre-driver circuit. The pre-driver circuit includes a first tri-state buffer having a data input, a control input, and an output, wherein the output of the first tri-state buffer is coupled to the first input of the driver. The pre-driver circuit also includes a second tri-state buffer having a data input, a control input, and an output, wherein the output of the second tri-state buffer is coupled to the second input of the driver. The chip also includes a trigger circuit coupled to the control input of the first tri-state buffer and the control input of the second tri-state buffer, wherein the trigger circuit is configured to detect an electrostatic discharge (ESD) event on the pad, and, in response to the detected ESD event, put each of the first tri-state buffer and the second tri-state buffer in a high output impedance state.

A second aspect relates to a chip. The chip includes a pad, and a driver having a first input, a second input, and an output, wherein the output of the driver is coupled to the pad. The chip also includes a pre-driver circuit. The pre-driver circuit includes a first tri-state buffer having a data input, a control input, and an output, wherein the output of the first tri-state buffer is coupled to the first input of the driver. The pre-driver circuit also includes a second tri-state buffer having a data input, a control input, and an output, wherein the output of the second tri-state buffer is coupled to the second input of the driver. The chip also includes a trigger circuit. The trigger circuit includes a resistor coupled between a first bus and a node, wherein the node is coupled to the control input of the first tri-state buffer and the control input of the second tri-state buffer. The trigger circuit also includes a capacitor coupled between the node and a second bus.

A third aspect relates to a method for electrostatic discharge (ESD) protection of a chip. The chip includes a driver, a first tri-state buffer, and a second tri-state buffer, wherein an output of the driver is coupled to a pad, an output of the first tri-state buffer is coupled to a first input of the driver, and an output of the second tri-state buffer is coupled to a second input of the driver. The method includes, during a normal mode, driving the first input of the driver with a first data signal using the first tri-state buffer and driving the second input of the driver with a second data signal using the second tri-state buffer. The method also includes detecting an ESD event on the pad, and, in response to detecting the ESD event, putting each of the first tri-state buffer and the second tri-state buffer in a high impedance output state.

### BRIEF DESCRIPTION OF THE DRAWINGS

FIG. 1 shows an example of a chip including a pad, a driver, and diodes for ESD

protection according to certain aspects of the present disclosure.

FIG. 2 shows an exemplary implementation of the driver according to certain aspects of the present disclosure.

FIG. 3 shows an example in which a pre-driver is configured to float the gates of transistors in the driver according to certain aspects of the present disclosure.

FIG. 4 shows an example in which floating the gate of a transistor in a stack of transistors helps split an ESD voltage between the transistors in the stack according to certain aspects of the present disclosure.

FIG. 5 shows an example in which the pre-driver includes tri-state buffers coupled to a trigger circuit according to certain aspects of the present disclosure.

FIG. 6 shows an example in which the trigger circuit includes a resistor-capacitor (RC) trigger according to certain aspects of the present disclosure.

FIG. 7 shows an example in which the trigger circuit is also used to trigger a power clamp according to certain aspects of the present disclosure.

FIG. 8 shows an exemplary implementation of the tri-state buffers according to certain aspects of the present disclosure.

FIG. 9 is a flowchart illustrating a method for ESD protection according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

A chip typically includes one or more ESD protection circuits to protect electronic components on the chip against ESD events. An ESD event may occur, for example, when a charged object makes contact with an input/output (I/O) pad of the chip (e.g., during handling of the chip). An ESD event may also occur, for example, when the chip acquires charge and then discharges to an object making contact with an I/O pad of the chip. An on-chip ESD protection scheme may include one or more power clamps, one or more diodes, or a combination thereof.

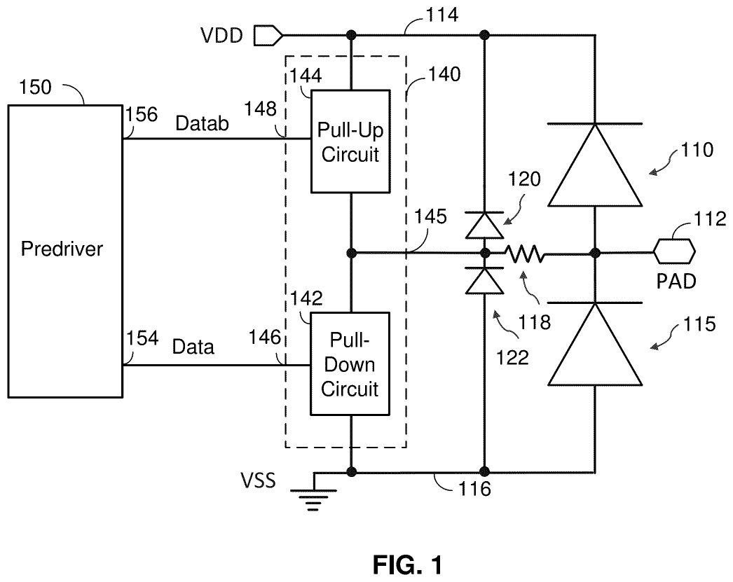

In this regard, FIG. 1 shows an example of an ESD protection scheme implemented on a chip. In this example, the chip includes a driver 140, an input/output (I/O) pad 112, and a pre-driver 150. The driver 140 has an output 145 coupled to the I/O pad 112. The I/O pad 112 may be coupled to a transmission line (not shown), in which the driver 140 is configured to drive the I/O pad 112 with a data signal to transmit data across the transmission line. The other end of the transmission line may be coupled to another chip (not shown) including a receiver configured to receive the data signal for chip-to-chip communication. It is to be appreciated that an ESD event may occur before the I/O pad 112 on the chip is coupled to the transmission line (e.g., during handling and packaging of the chip).

In the example shown in FIG. 1, the driver 140 includes a pull-up circuit 144 and a pull-down circuit 142. The pull-up circuit 144 is coupled between a first bus 114 (e.g., supply bus) and the output 145 of the driver 140, and the pull-down circuit 142 is coupled between the output 145 of the driver 140 and a second bus 116 (e.g., ground bus). During normal operation, the first bus 114 provides a supply voltage VDD to power the driver 140. In this example, the first bus 114 may also be referred to as a VDD bus, the power bus, the supply bus, or another term. It is to be appreciated that an ESD event may occur during a time when the supply voltage VDD is not provided to the first bus 114 (e.g., the chip is not powered on by a supply voltage source).

The pre-driver 150 has a first output 154 coupled to a first input 146 of the driver 140 and a second output 156 coupled to a second input 148 of the driver 140. During normal operation, the pre-driver 150 is configured to drive the first input 146 of the driver 140 with the data signal Data and drive the second input 148 of the driver 140 with the data signal Datab, which may be the complement of the data signal Data. When the data signals Data and Datab are high and low, respectively, the pull-down circuit 142 pulls the output 145 of the driver 140 and the I/O pad 112 low (e.g., to ground potential). When the data signals Data and Datab are low and high, respectively, the pull-up circuit 144 pulls the output 145 of the driver 140 and the I/O pad high (i.e., to the supply voltage VDD).

Because the I/O pad 112 provides an interface between the external world and internal circuitry (e.g., the driver 140) of the chip, an ESD protection circuit is provided at the pad 112 to protect the internal circuitry from damage due to ESD. In the example in FIG. 1, the ESD circuit includes a first diode 110, a second diode 115, a third diode 120, a fourth diode 122, and a resistor 118. The ESD circuit may also include a power clamp (not shown in FIG. 1) coupled between the first bus 114 and the second bus 116.

In this example, the first diode 110 is coupled between the I/O pad 112 and the first bus 114 and the second diode 115 is coupled between the second bus 116 and the I/O pad 112. The third diode 120 is coupled between the output 145 of the driver 140 and the first bus 114 and the fourth diode 122 is coupled between the second bus 116 and the output 145 of the driver 140. The resistor 118 is coupled between the output 145 of the driver 140 and the I/O pad 112.

During an ESD event, one or more of the diodes 110, 115, 120, and 122 turn on to provide one or more current paths between the I/O pad 112 and the first bus 114 and/or one or more current paths between the I/O pad 112 and the second bus 116. The resistor 118 is used to provide a current-resistor (IR) voltage drop between the I/O pad 112 and the output 145 of the driver 140 during an ESD event to reduce the voltage at the output 145 of the driver 140.

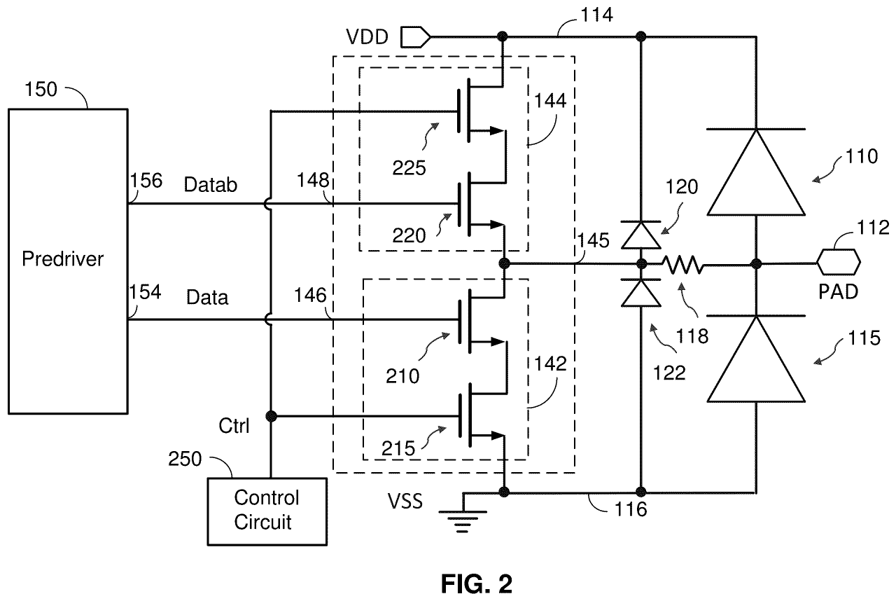

FIG. 2 shows an exemplary implementation of the pull-down circuit 142 and the pull-up circuit 144 according to certain aspects. The pull-down circuit 142 includes a first transistor 210 and a second transistor 215 that are stacked between the output 145 of the driver 140 and the second bus 116. The pull-up circuit 144 includes a third transistor 220 and a fourth transistor 225 that are stacked between the first bus 114 and the output 145 of the driver 140. In the example shown in FIG. 2, each of the transistors 210, 215, 220, and 225 is implemented with a respective n-type field effect transistor (NFET). However, it is to be appreciated that the present disclosure is not limited to this example.

The gates of the second transistor 215 and the fourth transistor 225 are coupled to a control circuit 250. The control circuit 250 outputs a control signal Ctrl to the gates of the transistors 215 and 225 that controls whether the driver 140 is enabled or disabled. To enable the driver 140, the control signal Ctrl turns on the transistors 215 and 225, and, to disable the driver 140, the control signal Ctrl turns off the transistors 215 and 225. For the example where each of the transistors 215 and 225 is implemented with a respective NFET, the control signal Ctrl turns on the transistors 215 and 225 when the control signal Ctrl is high (e.g., VDD) and turns off the transistors 215 and 225 when the control signal Ctrl is low (e.g., ground potential).

The gate of the first transistor 210 is coupled to the first input 146 of the driver 140 to receive the data signal Data and the gate of the third transistor 220 is coupled to the second input 148 of the driver 140 to receive the data signal Datab, which is the complement of the data signal Data. When the driver 140 is enabled, the transistors 210 and 220 are configured to drive the I/O pad 112 based on the data signals Data and Datab, respectively, from the pre-driver 150. When the data signals Data and Datab are high and low, respectively, the first transistor 210 pulls the output 145 and the I/O pad 112 low (e.g., to ground potential). When the data signals Data and Datab are low and high, respectively, the third transistor 220 pulls the output 145 and the I/O pad 112 high (e.g., to VDD). In this regard, the first transistor 210 may also be referred to as a pull-down transistor and the third transistor 220 may also be referred to as a pull-up transistor.

In advanced process nodes, the transistors 210, 215, 220, and 225 are implemented with thin-oxide devices. This reduces the drain-to-source voltage (VDS) limits of the transistors 210, 215, 220, and 225, which makes providing ESD protection for the driver 140 more challenging. In addition, the VDS limits of these devices are becoming a strong function of terminal gate-to-source voltage (VGS), requiring that the voltage across each device be monitored (e.g., for electrical safe operating area (eSOA) based sign-off).

During an ESD event, the voltages at the gates of the transistors 210 and 220 are uncontrolled (unknown). This can cause the entire voltage of the ESD event to drop across one of the transistors 210 and 215 in the pull-down circuit 142 and/or across one of the transistors 220 and 225 in the pull-up circuit 144. Dropping the entire voltage across one of the transistors pushes the transistor closer to gate-oxide breakdown.

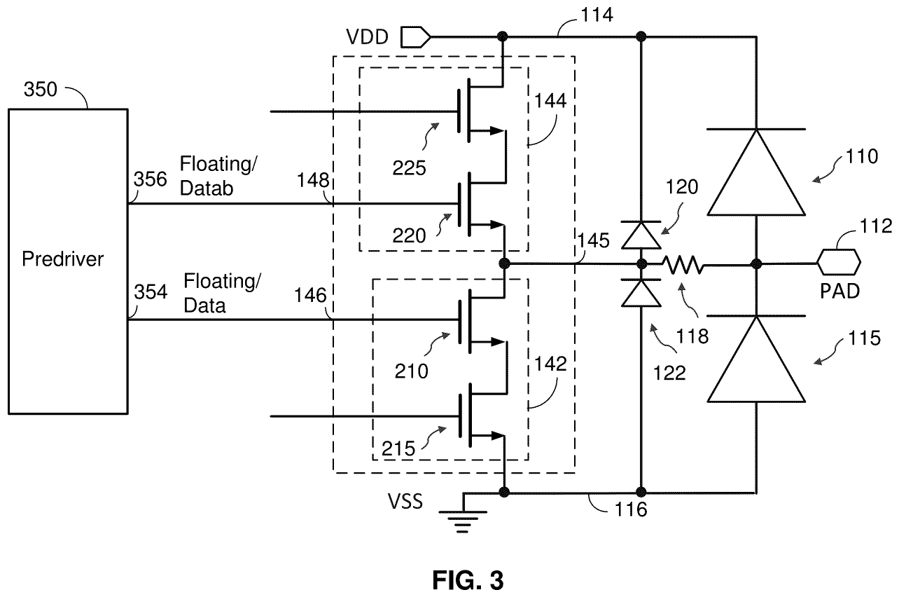

To address the above, aspects of the present disclosure provides a pre-driver 350 (shown in FIG. 3) configured to float the gates of the transistors 210 and 220 during an ESD event. Floating the gate of the first transistor 210 helps split the voltage of the ESD event between the transistors 210 and 215 in the pull-down circuit 142, which prevents the entire voltage of the ESD event from appearing across one of the transistors 210 and 215 and potentially causing gate-oxide breakdown. Floating the gate of the third transistor 220 helps split the voltage of the ESD event between the transistors 220 and 225 in the pull-up circuit 144, which prevents the entire voltage of the ESD event from appearing across one of the transistors 220 and 225 and potentially causing gate-oxide breakdown.

In the example shown in FIG. 3, the pre-driver 350 has a first output 354 coupled to the gate of the first transistor 210 in the pull-down circuit 142 and a second output 356 coupled to the gate of the third transistor 220 in the pull-up circuit 144. During normal operation, the pre-driver 150 is configured to drive the gate of the first transistor 210 with the data signal Data and drive the gate of the third transistor 220 with the data signal Datab, as discussed above.

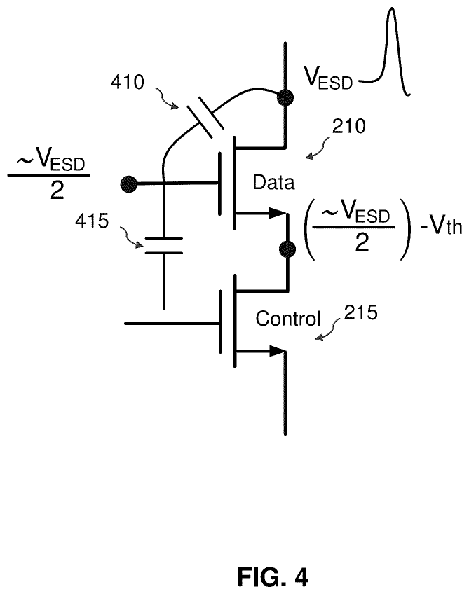

During an ESD event, the pre-driver 350 is configured to float the gates of the transistors 210 and 225. As discussed above, floating the gate of the first transistor 210 helps split the voltage of the ESD event between the transistors 210 and 215 in the pull-down circuit 142, which prevents the entire voltage of the ESD event from appearing across one of the transistors 210 and 215 and potentially causing gate-oxide breakdown. In this regard, FIG. 4 shows an example in which floating the gate of the first transistor 210 helps split the voltage of the ESD event between the transistors 210 and 215.

In the example in FIG. 4, parasitic capacitances 410 and 415 of the transistors 210 and 215 form a capacitive voltage divider, in which the capacitance 415 may be between the floating gate of the transistor 210 and ground during the ESD event. In this example, the capacitive voltage divider causes the voltage at the gate of the transistor 210 to be approximately equal to V_{ESD}/2 during the ESD event where V_{ESD} is the voltage of the ESD event at the output 145 of the driver 140. Having the pre-driver 350 float the gate of the transistor 210 during the ESD event allows the capacitive voltage divider to control the voltage at the gate of the first transistor 210 during the ESD event. In the example in FIG. 4, the voltage of approximately V_{ESD}/2 at the gate of the first transistor 210 causes the first transistor 210 to partially turn on and the voltage at the drain of the second transistor 215 to be approximately equal to V_{ESD}/2−Vth where Vth is the threshold voltage of the first transistor 210. Thus, the ESD voltage V_{ESD} is split between the transistors 210 and 215, which prevents the entire ESD voltage V_{ESD} from appearing across one of the transistors and potentially causing gate-oxide breakdown.

Floating the gate of the third transistor 220 in the pull-up circuit 144 also helps split the voltage of the ESD event between the transistors 220 and 225 in the pull-up circuit 144 for similar reasons.

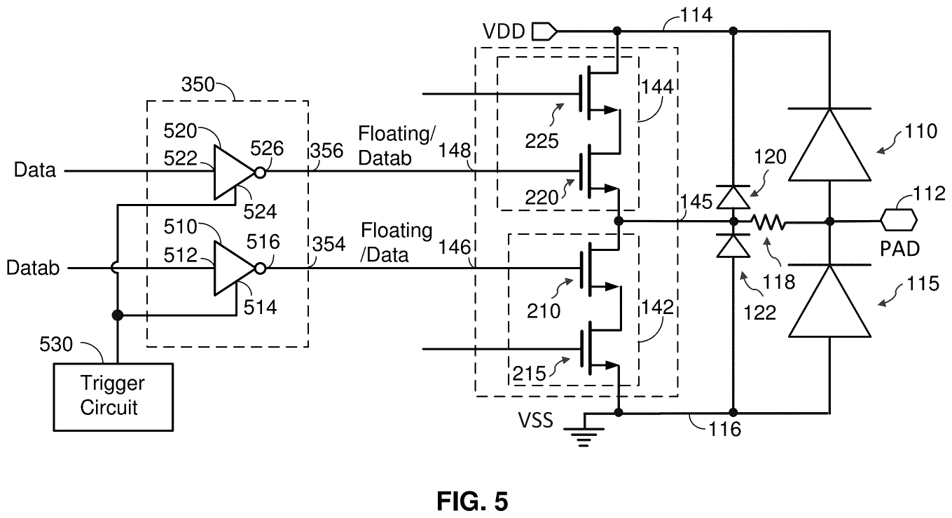

FIG. 5 shows an exemplary implementation of the pre-driver 350. In this example, the pre-driver 350 includes a first tri-state buffer 510, a second tri-state buffer 520, and a trigger circuit 530. Each of the tri-state buffers 510 and 520 may be implemented with a respective tri-state inverter (shown in the example in FIG. 5) or a non-inverting tri-state buffer. As used herein, a “tri-state buffer” is a buffer that has a high output state (i.e., logic one), a low logic output state (i.e., logic zero), or a high impedance output state (i.e., hi-Z).

The first tri-state buffer 510 includes a data input 512, a control input 514, and an output 516 coupled to the gate of the first transistor 210. The control input 514 is coupled to the trigger circuit 530 (e.g., a resistor-capacitor (RC) trigger). During normal operation, the trigger circuit 530 is configured to enable the pre-driver function of the first tri-state buffer 510 in which the first tri-state buffer 510 receives the data signal Datab at the data input 512 and pre-drives the gate of the first transistor 210 based on the data signal Datab. In the example in which the first tri-state buffer 510 is implemented with a tri-state inverter, the first tri-state buffer 510 inverts the data signal Datab into the data signal Data and pre-drives the gate of the first transistor 210 with the data signal Data.

During an ESD event, the trigger circuit 530 is configured to detect the ESD event and, in response to the detected ESD event, put the first tri-state buffer 510 in the high impedance output state, in which the impedance at the output 516 is very high. The very high impedance at the output 516 floats the gate of the first transistor 210, which helps split the ESD voltage between the transistors 210 and 215 in the pull-down circuit 142, as discussed above.

In this example, ESD protection is incorporated into the first tri-state buffer 510 by having the trigger circuit 530 put the first tri-state buffer 510 in the high output impedance state during the ESD event to float the gate of the first transistor 210. Incorporating the ESD protection into the first tri-state buffer 510 eliminates the need for placing additional logic or an RC filter in the data path to the first transistor 210 where the additional logic or RC filter may disturb the data signal. In other words, incorporating the ESD protection into the first tri-state buffer 510 provides a clean data path to the first transistor 210, which improves bandwidth for higher data rates.

The second tri-state buffer 520 includes a data input 522, a control input 524, and an output 526 coupled to the gate of the third transistor 220. The control input 524 is coupled to the trigger circuit 530. During normal operation, the trigger circuit 530 is configured to enable the pre-driver function of the second tri-state buffer 520 in which the second tri-state buffer 520 receives the data signal Data at the data input 522 and pre-drives the gate of the third transistor 220 based on the data signal Datab. In the example in which the second tri-state buffer 520 is implemented with a tri-state inverter, the second tri-state buffer 520 inverts the data signal Data into the data signal Datab and pre-drives the gate of the third transistor 220 with the data signal Datab.

During an ESD event, the trigger circuit 530 is configured to detect the ESD event and, in response to the detected ESD event, put the second tri-state buffer 520 in the high impedance output state, in which the impedance at the output 526 is very high. The very high impedance at the output 526 floats the gate of the third transistor 220, which helps split the ESD voltage between the transistors 220 and 225 in the pull-up circuit 144, as discussed above.

In this example, ESD protection is incorporated into the second tri-state buffer 520 by having the trigger circuit 530 put the second tri-state buffer 520 in the high output impedance state during the ESD event to float the gate of the third transistor 220. Incorporating the ESD protection into the second tri-state buffer 520 eliminates the need for placing additional logic or an RC filter in the data path to the third transistor 220 where the additional logic or RC filter may disturb the data signal. In other words, incorporating the ESD protection into the second tri-state buffer 520 provides a clean data path to the third transistor 220, which improves bandwidth for higher data rates.

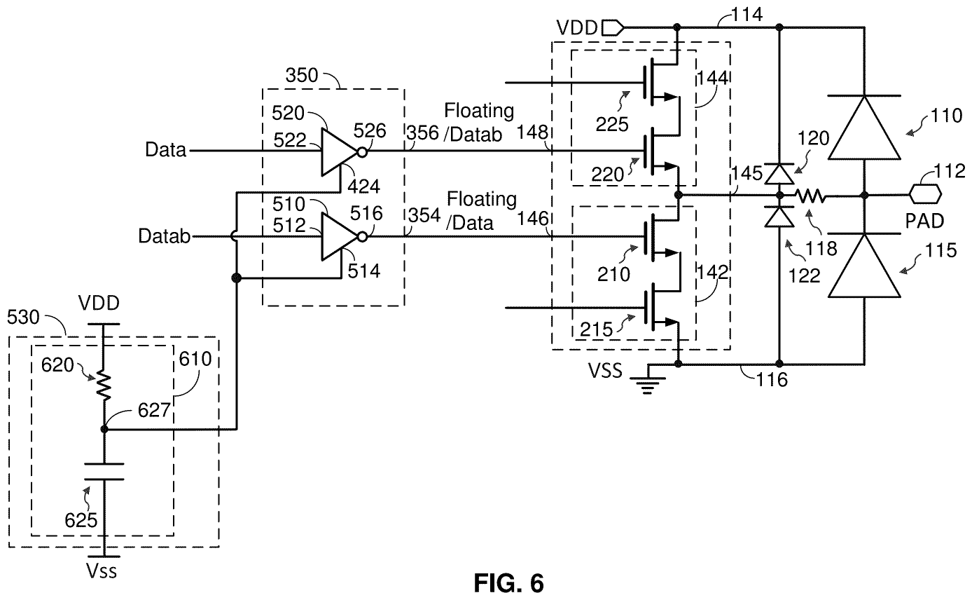

FIG. 6 shows an exemplary implementation of the trigger circuit 530. In this example, the trigger circuit 530 is implemented with an RC trigger 610 including a resistor 620 and a capacitor 625. The resistor 620 is coupled between the first bus 114 (e.g., VDD bus) and a node 627, and the capacitor 625 is coupled between the node 627 and the second bus 116 (e.g., VSS bus). The node 627 is coupled to the control input 514 of the first tri-state buffer 510 and the control input 524 of the second tri-state buffer 520.

In this example, the first tri-state buffer 510 and the second tri-state buffer 520 are enabled when the node 627 is high, and the first tri-state buffer 510 and the second tri-state buffer 520 are disabled (i.e., placed in the high impedance output state) when the node is low. During normal operation, the capacitor 625 is charged to the supply voltage VDD on the first bus 114 through the resistor 620. As a result, the node 627 is high during normal operation. During an ESD event, the node 627 is low. This is because the capacitor 625 does not have time to charge up during the ESD event assuming the transient voltage of the ESD event is faster than the RC time constant of the RC trigger 610.

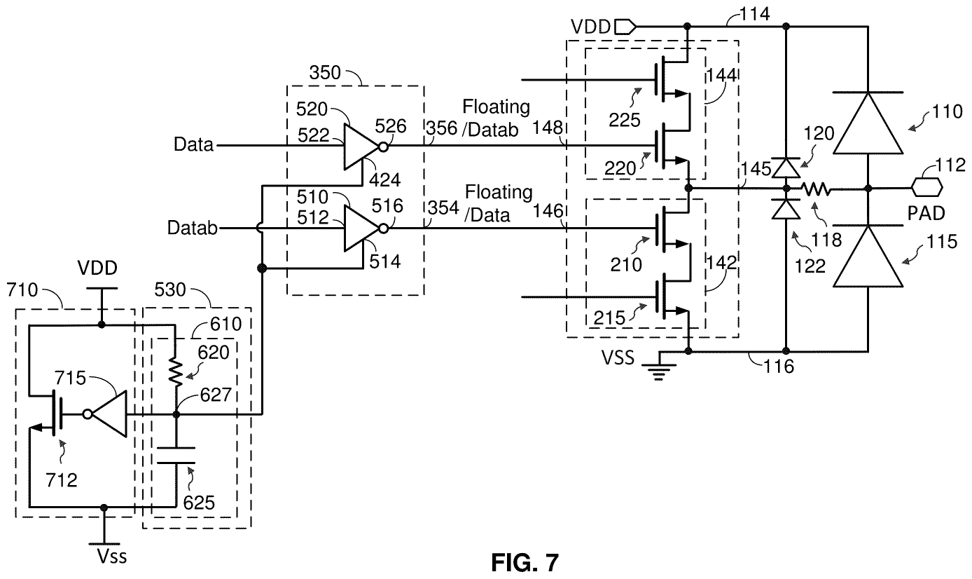

The RC trigger 610 may also be used to trigger a power clamp. In this regard, FIG. 7 shows an example of a power clamp 710 coupled between the first bus 114 and the second bus 116. The power clamp 710 includes a clamp transistor 712 (e.g., an NFET) and an inverter 715. The drain of the clamp transistor 712 is coupled to the first bus 114 and the source of the transistor 712 is coupled to the second bus 116. The input of the inverter 715 is coupled to the node 627 of the RC trigger 610 and the output of the inverter 715 is coupled to the gate of the clamp transistor 712. In this example, the clamp transistor 712 turns off when the gate of the clamp transistor 712 is low and turns on when the gate of the clamp transistor is driven high.

During normal operation, the clamp transistor 712 is turned off. This is because the node 627 is high during normal operation, which causes the inverter 715 to drive the gate of the clamp transistor 712 low and turn off the clamp transistor 712.

During an ESD event, the clamp transistor 712 is turned on. This is because the node 627 is low during the ESD event, which causes the inverter 715 to drive the gate of the clamp transistor 712 high and turn on the clamp transistor 712. Turning on the clamp transistor 712 creates a current path between the first bus 114 and the second bus 116 through the clamp transistor 712 during the ESD event. The current path allows ESD current to flow between the buses 114 and 116.

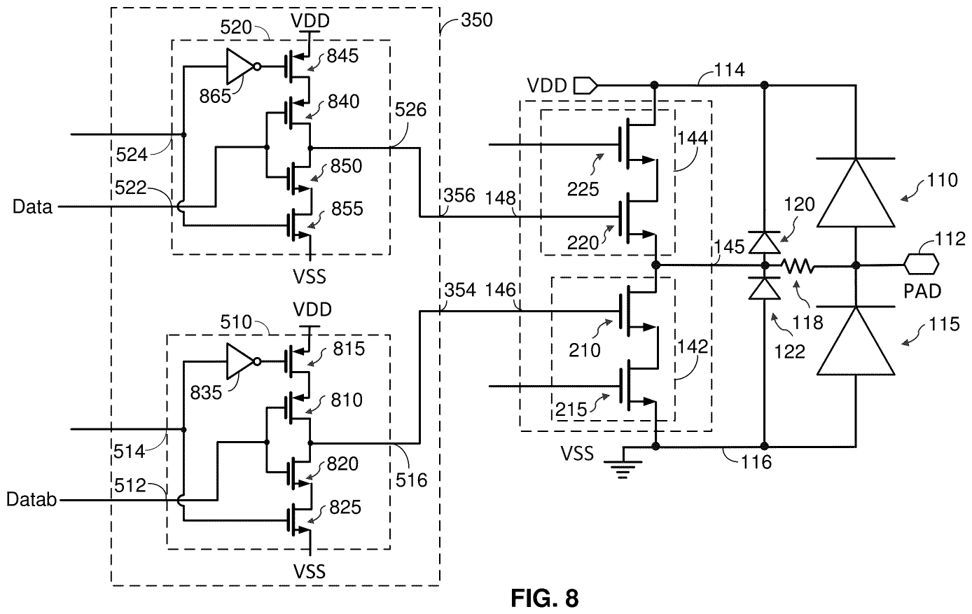

FIG. 8 shows an exemplary implementation of the first tri-state buffer 510 and the second tri-state buffer 520 according to certain aspects of the present disclosure.

In this example, the first tri-state buffer 510 includes a first transistor 810 and a second transistor 815 coupled in a stack between the first bus 114 and the output 516 of the first tri-state buffer 510. The first tri-state buffer 510 also includes a third transistor 820 and a fourth transistor 825 coupled in a stack between the output 516 of the first tri-state buffer 510 and the second bus 116. In the example shown in FIG. 8, each of the first transistor 810 and the second transistor 815 is implemented with a respective PFET, and each of the third transistor 820 and the fourth transistor 825 is implemented with a respective NFET. However, it is to be appreciated that the present disclosure is not limited to this example.

In the example in FIG. 8, the gates of the first transistor 810 and the third transistor 820 are coupled to the data input 512 and the drains of the first transistor 810 and the third transistor 820 are coupled to the output 516. The second transistor 815 is coupled between the source of the first transistor 810 and the first bus 114, and the fourth transistor 825 is coupled between the source of the third transistor 820 and the second bus 116. The gate of the second transistor 815 is coupled to the control input 514 through an inverter 835, and the gate of the fourth transistor 825 is coupled to the control input 514. However, it is to be appreciated that the present disclosure is not limited to this example.

During normal operation, the trigger circuit 530 (shown in FIG. 5) turns on the transistors 815 and 825. As a result, the source of the first transistor 810 is coupled to the first bus 114 through the second transistor 815, and the source of the third transistor 820 is coupled to the second bus 116 through the fourth transistor 825. This allows the first transistor 810 and the third transistor 820 to function as an inverter that inverts the data signal Datab into the data signal Data and pre-drives the gate of the first input 146 of the driver 140 with the data signal Data.

During an ESD event, the trigger circuit 530 turns off the transistors 815 and 825. This causes the impedance at the output 516 of the first tri-state buffer 510 to be very high (i.e., hi-Z) since the transistors 815 and 825 have high impedance when they are turned off.

In this example, the second tri-state buffer 520 includes a first transistor 840 and a second transistor 845 coupled in a stack between the first bus 114 and the output 526 of the second tri-state buffer 520. The second tri-state buffer 520 also includes a third transistor 850 and a fourth transistor 855 coupled in a stack between the output 526 of the second tri-state buffer 520 and the second bus 116. In the example shown in FIG. 8, each of the first transistor 840 and the second transistor 845 is implemented with a respective PFET, and each of the third transistor 850 and the fourth transistor 855 is implemented with a respective NFET. However, it is to be appreciated that the present disclosure is not limited to this example.

In the example in FIG. 8, the gates of the first transistor 840 and the third transistor 850 are coupled to the data input 522 and the drains of the first transistor 840 and the third transistor 850 are coupled to the output 526. The second transistor 845 is coupled between the source of the first transistor 840 and the first bus 114, and the fourth transistor 855 is coupled between the source of the third transistor 850 and the second bus 116. The gate of the second transistor 845 is coupled to the control input 524 through an inverter 865, and the gate of the fourth transistor 855 is coupled to the control input 524. However, it is to be appreciated that the present disclosure is not limited to this example.

During normal operation, the trigger circuit 530 (shown in FIG. 5) turns on the transistors 845 and 855. As a result, the source of the first transistor 840 is coupled to the first bus 114 through the second transistor 845, and the source of the third transistor 850 is coupled to the second bus 116 through the fourth transistor 855. This allows the first transistor 840 and the third transistor 850 to function as an inverter that inverts the data signal Data into the data signal Datab and pre-drives the gate of the second input 148 of the driver 140 with the data signal Datab.

During an ESD event, the trigger circuit 530 turns off the transistors 845 and 855. This causes the impedance at the output 526 of the second tri-state buffer 520 to be very high (i.e., hi-Z) since the transistors 845 and 855 have high impedance when they are turned off.

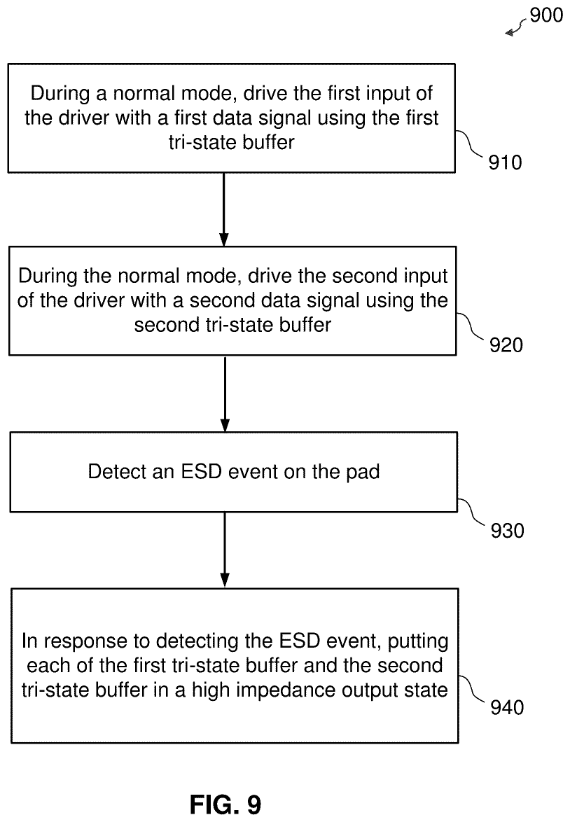

FIG. 9 shows an example of a method 900 for ESD protection of a chip according to certain aspects. The chip includes a driver (e.g., the driver 140), a first tri-state buffer (e.g., the first tri-state buffer 510), and a second tri-state buffer (e.g., the second tri-state buffer 520), wherein an output of the driver (e.g., output 145) is coupled to a pad (e.g., the pad 112), an output (e.g., output 516) of the first tri-state buffer is coupled to a first input (e.g., first input 146) of the driver, and an output (e.g., output 526) of the second tri-state buffer is coupled to a second input (e.g., second input 148) of the driver.

At block 910, during a normal mode, the first input of the driver is driven with a first data signal using the first tri-state buffer. For example, the first data signal may correspond to data signal Data.

At block 920, during the normal mode, the second input of the driver is driven with a second data signal using the second tri-state buffer. For example, the second data signal may correspond to the data signal Datab.

At block 930, an ESD event on the pad is detected. For example, the ESD event may be detected by the trigger circuit 530.

At block 940, in response to detecting the ESD event, each of the first tri-state buffer and the second tri-state buffer is put in a high impedance output state. For example, the trigger circuit 530 may put each of the first tri-state buffer and the second tri-state buffer in the high impedance output state (e.g., by turning off the transistors 815 and 825 in the first tri-state buffer 510 and turning off the transistors 845 and 855 in the second tri-state buffer 520).

In certain aspects, the first tri-state buffer includes a first tri-state inverter and the second tri-state buffer includes a second tri-state inverter.

Implementation examples are described in the following numbered clauses:
1. A chip, comprising:
a pad;
a driver having a first input, a second input, and an output, wherein the output of the driver is coupled to the pad;
a pre-driver circuit, comprising:
   a first tri-state buffer having a data input, a control input, and an output, wherein the output of the first tri-state buffer is coupled to the first input of the driver; and
   a second tri-state buffer having a data input, a control input, and an output, wherein the output of the second tri-state buffer is coupled to the second input of the driver; and
a trigger circuit coupled to the control input of the first tri-state buffer and the control input of the second tri-state buffer, wherein the trigger circuit is configured to detect an electrostatic discharge (ESD) event on the pad, and, in response to the detected ESD event, put each of the first tri-state buffer and the second tri-state buffer in a high output impedance state.
2. The chip of clause 1, wherein the first tri-state buffer comprises a first tri-state inverter and the second tri-state buffer comprises a second tri-state inverter.
3. The chip of clause 1 or 2, wherein the trigger circuit comprises:
a resistor coupled between a first bus and a node, wherein the node is coupled to the control input of the first tri-state buffer and the control input of the second tri-state buffer; and
a capacitor coupled between the node and a second bus.
4. The chip of clause 3, wherein the first bus comprises a supply bus.
5. The chip of clause 3 or 4, wherein the driver comprises:
a first stack of transistors coupled between the output of the driver and the second bus, wherein the first stack of transistors includes a pull-down transistor having a gate coupled to the output of the first tri-state buffer; and
a second stack of transistors coupled between the output of the driver and the first bus, wherein the second stack of transistors includes a pull-up transistor having a gate coupled to the output of the second tri-state buffer.
6. The chip of any one of clauses 1 to 5, wherein the first tri-state buffer comprises:
a first transistor, wherein a gate of the first transistor is coupled to the data input of the first tri-state buffer, and a drain of the first transistor is coupled to the output of the first tri-state buffer;
a second transistor, wherein the second transistor is coupled between a source of the first transistor and a first bus, and a gate of the second transistor is coupled to the control input of the first tri-state buffer;
a third transistor, wherein a gate of the third transistor is coupled to the data input of the first tri-state buffer, and a drain of the third transistor is coupled to the output of the first tri-state buffer; and
a fourth transistor, wherein the fourth transistor is coupled between a source of the third transistor and a second bus, and a gate of the fourth transistor is coupled to the control input of the first tri-state buffer.
7. The chip of clause 6, wherein the first tri-state buffer further comprises an inverter coupled between the control input of the first tri-state buffer and the gate of the second transistor.
8. The chip of clause 6 or 7, wherein each of the first transistor and the second transistor comprises a respective p-type field effect transistor (PFET), and each of the third transistor and the fourth transistor comprises a respective n-type field effect transistor (NFET).
9. The chip of any one of clauses 6 to 8 wherein the first bus comprises a supply bus.
10. The chip of any one of clauses 6 to 9, wherein the trigger circuit comprises:
a resistor coupled between the first bus and a node, wherein the node is coupled to the control input of the first tri-state buffer and the control input of the second tri-state buffer; and
a capacitor coupled between the node and the second bus.
11. The chip of any one of clauses 6 to 10, wherein the second tri-state buffer comprises:
a fifth transistor, wherein a gate of the fifth transistor is coupled to the data input of the second tri-state buffer, and a drain of the fifth transistor is coupled to the output of the second tri-state buffer;
a sixth transistor, wherein the sixth transistor is coupled between a source of the fifth transistor and the first bus, and a gate of the sixth transistor is coupled to the control input of the second tri-state buffer;
a seventh transistor, wherein a gate of the seventh transistor is coupled to the data input of the second tri-state buffer, and a drain of the seventh transistor is coupled to the output of the second tri-state buffer; and
an eighth transistor, wherein the eighth transistor is coupled between a source of the seventh transistor and the second bus, and a gate of the eighth transistor is coupled to the control input of the second tri-state buffer.
12. The chip of clause 11, wherein the first tri-state buffer further comprises a first inverter coupled between the control input of the first tri-state buffer and the gate of the second transistor, and the second tri-state buffer comprises a second inverter coupled between the control input of the second tri-state buffer and the gate of the sixth transistor.
13. The chip of clause 11 or 12, wherein each of the first transistor, the second transistor, the fifth transistor, and the sixth transistor comprises a respective p-type field effect transistor (PFET), and each of the third transistor, the fourth transistor, the seventh transistor, and the eighth transistor comprises a respective n-type field effect transistor (NFET).
14. The chip of any one of clauses 11 to 13, wherein the first bus comprises a supply bus.
15. The chip of any one of clauses 11 to 14, wherein the trigger circuit comprises:
a resistor coupled between the first bus and a node, wherein the node is coupled to the control input of the first tri-state buffer and the control input of the second tri-state buffer; and
a capacitor coupled between the node and the second bus.
16. A chip, comprising:
a pad;
a driver having a first input, a second input, and an output, wherein the output of the driver is coupled to the pad;
a pre-driver circuit, comprising:
   a first tri-state buffer having a data input, a control input, and an output, wherein the output of the first tri-state buffer is coupled to the first input of the driver; and
   a second tri-state buffer having a data input, a control input, and an output, wherein the output of the second tri-state buffer is coupled to the second input of the driver; and
a trigger circuit, comprising:
   a resistor coupled between a first bus and a node, wherein the node is coupled to the control input of the first tri-state buffer and the control input of the second tri-state buffer; and
   a capacitor coupled between the node and a second bus.
17. The chip of clause 16, wherein the first tri-state buffer comprises a first tri-state inverter and the second tri-state buffer comprises a second tri-state inverter.
18. The chip of clause 16 or 17, wherein the first tri-state buffer comprises:
a first transistor, wherein a gate of the first transistor is coupled to the data input of the first tri-state buffer, and a drain of the first transistor is coupled to the output of the first tri-state buffer;
a second transistor, wherein the second transistor is coupled between a source of the first transistor and the first bus, and a gate of the second transistor is coupled to the control input of the first tri-state buffer;
a third transistor, wherein a gate of the third transistor is coupled to the data input of the first tri-state buffer, and a drain of the third transistor is coupled to the output of the first tri-state buffer; and
a fourth transistor, wherein the fourth transistor is coupled between a source of the third transistor and the second bus, and a gate of the fourth transistor is coupled to the control input of the first tri-state buffer.
19. The chip of clause 18, wherein the first tri-state buffer further comprises an inverter coupled between the control input of the first tri-state buffer and the gate of the second transistor.
20. The chip of clause 18 or 19, wherein each of the first transistor and the second transistor comprises a respective p-type field effect transistor (PFET), and each of the third transistor and the fourth transistor comprises a respective n-type field effect transistor (NFET).
21. A method for electrostatic discharge (ESD) protection of a chip including a driver, a first tri-state buffer, and a second tri-state buffer, wherein an output of the driver is coupled to a pad, an output of the first tri-state buffer is coupled to a first input of the driver, and an output of the second tri-state buffer is coupled to a second input of the driver, the method comprising:
during a normal mode, driving the first input of the driver with a first data signal using the first tri-state buffer;
during the normal mode, driving the second input of the driver with a second data signal using the second tri-state buffer;
detecting an ESD event on the pad; and
in response to detecting the ESD event, putting each of the first tri-state buffer and the second tri-state buffer in a high impedance output state.
22. The method of clause 21, wherein the first tri-state buffer comprises a first tri-state inverter and the second tri-state buffer comprises a second tri-state inverter.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures unless otherwise specified. It is also to be appreciated that an output may include multiple parallel outputs, and that an input may include multiple parallel inputs.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a pad;
a driver having a first input, a second input, and an output, wherein the output of the driver is coupled to the pad;
a pre-driver circuit, comprising:
a first tri-state buffer having a data input, a control input, and an output, wherein the output of the first tri-state buffer is coupled to the first input of the driver; and
a second tri-state buffer having a data input, a control input, and an output, wherein the output of the second tri-state buffer is coupled to the second input of the driver; and
a trigger circuit coupled to the control input of the first tri-state buffer and the control input of the second tri-state buffer, wherein the trigger circuit is configured to detect an electrostatic discharge (ESD) event on the pad, and, in response to the detected ESD event, put each of the first tri-state buffer and the second tri-state buffer in a high output impedance state.

2. The chip of claim 1, wherein the first tri-state buffer comprises a first tri-state inverter and the second tri-state buffer comprises a second tri-state inverter.

3. The chip of claim 1, wherein the trigger circuit comprises:
a resistor coupled between a first bus and a node, wherein the node is coupled to the control input of the first tri-state buffer and the control input of the second tri-state buffer; and
a capacitor coupled between the node and a second bus.

4. The chip of claim 3, wherein the first bus comprises a supply bus.

5. The chip of claim 3, wherein the driver comprises:
a first stack of transistors coupled between the output of the driver and the second bus, wherein the first stack of transistors includes a pull-down transistor having a gate coupled to the output of the first tri-state buffer; and
a second stack of transistors coupled between the output of the driver and the first bus, wherein the second stack of transistors includes a pull-up transistor having a gate coupled to the output of the second tri-state buffer.

6. The chip of claim 1, wherein the first tri-state buffer comprises:
a first transistor, wherein a gate of the first transistor is coupled to the data input of the first tri-state buffer, and a drain of the first transistor is coupled to the output of the first tri-state buffer;
a second transistor, wherein the second transistor is coupled between a source of the first transistor and a first bus, and a gate of the second transistor is coupled to the control input of the first tri-state buffer;
a third transistor, wherein a gate of the third transistor is coupled to the data input of the first tri-state buffer, and a drain of the third transistor is coupled to the output of the first tri-state buffer; and
a fourth transistor, wherein the fourth transistor is coupled between a source of the third transistor and a second bus, and a gate of the fourth transistor is coupled to the control input of the first tri-state buffer.

7. The chip of claim 6, wherein the first tri-state buffer further comprises an inverter coupled between the control input of the first tri-state buffer and the gate of the second transistor.

8. The chip of claim 6, wherein each of the first transistor and the second transistor comprises a respective p-type field effect transistor (PFET), and each of the third transistor and the fourth transistor comprises a respective n-type field effect transistor (NFET).

9. The chip of claim 6, wherein the first bus comprises a supply bus.

10. The chip of claim 6, wherein the trigger circuit comprises:
a resistor coupled between the first bus and a node, wherein the node is coupled to the control input of the first tri-state buffer and the control input of the second tri-state buffer; and
a capacitor coupled between the node and the second bus.

11. The chip of claim 6, wherein the second tri-state buffer comprises:
a fifth transistor, wherein a gate of the fifth transistor is coupled to the data input of the second tri-state buffer, and a drain of the fifth transistor is coupled to the output of the second tri-state buffer;
a sixth transistor, wherein the sixth transistor is coupled between a source of the fifth transistor and the first bus, and a gate of the sixth transistor is coupled to the control input of the second tri-state buffer;
a seventh transistor, wherein a gate of the seventh transistor is coupled to the data input of the second tri-state buffer, and a drain of the seventh transistor is coupled to the output of the second tri-state buffer; and
an eighth transistor, wherein the eighth transistor is coupled between a source of the seventh transistor and the second bus, and a gate of the eighth transistor is coupled to the control input of the second tri-state buffer.

12. The chip of claim 11, wherein the first tri-state buffer further comprises a first inverter coupled between the control input of the first tri-state buffer and the gate of the second transistor, and the second tri-state buffer comprises a second inverter coupled between the control input of the second tri-state buffer and the gate of the sixth transistor.

13. The chip of claim 11, wherein each of the first transistor, the second transistor, the fifth transistor, and the sixth transistor comprises a respective p-type field effect transistor (PFET), and each of the third transistor, the fourth transistor, the seventh transistor, and the eighth transistor comprises a respective n-type field effect transistor (NFET).

14. The chip of claim 11, wherein the first bus comprises a supply bus.

15. The chip of claim 11, wherein the trigger circuit comprises:
a resistor coupled between the first bus and a node, wherein the node is coupled to the control input of the first tri-state buffer and the control input of the second tri-state buffer; and
a capacitor coupled between the node and the second bus.

16. A chip, comprising:
a pad;
a driver having a first input, a second input, and an output, wherein the output of the driver is coupled to the pad;
a pre-driver circuit, comprising:
a first tri-state buffer having a data input, a control input, and an output, wherein the output of the first tri-state buffer is coupled to the first input of the driver; and
a second tri-state buffer having a data input, a control input, and an output, wherein the output of the second tri-state buffer is coupled to the second input of the driver; and
a trigger circuit, comprising:
a resistor coupled between a first bus and a node, wherein the node is coupled to the control input of the first tri-state buffer and the control input of the second tri-state buffer; and
a capacitor coupled between the node and a second bus.

17. The chip of claim 16, wherein the first tri-state buffer comprises a first tri-state inverter and the second tri-state buffer comprises a second tri-state inverter.

18. The chip of claim 16, wherein the first tri-state buffer comprises:
a first transistor, wherein a gate of the first transistor is coupled to the data input of the first tri-state buffer, and a drain of the first transistor is coupled to the output of the first tri-state buffer;
a second transistor, wherein the second transistor is coupled between a source of the first transistor and the first bus, and a gate of the second transistor is coupled to the control input of the first tri-state buffer;
a third transistor, wherein a gate of the third transistor is coupled to the data input of the first tri-state buffer, and a drain of the third transistor is coupled to the output of the first tri-state buffer; and
a fourth transistor, wherein the fourth transistor is coupled between a source of the third transistor and the second bus, and a gate of the fourth transistor is coupled to the control input of the first tri-state buffer.

19. A method for electrostatic discharge (ESD) protection of a chip including a driver, a first tri-state buffer, and a second tri-state buffer, wherein an output of the driver is coupled to a pad, an output of the first tri-state buffer is coupled to a first input of the driver, and an output of the second tri-state buffer is coupled to a second input of the driver, the method comprising:
during a normal mode, driving the first input of the driver with a first data signal using the first tri-state buffer;
during the normal mode, driving the second input of the driver with a second data signal using the second tri-state buffer;
detecting an ESD event on the pad; and
in response to detecting the ESD event, putting each of the first tri-state buffer and the second tri-state buffer in a high impedance output state.

20. The method of claim 19, wherein the first tri-state buffer comprises a first tri-state inverter and the second tri-state buffer comprises a second tri-state inverter.
